(19) United States
(12) Patent Application Publication
(10) Pub. No.: US 2006/0023441 A1
(43) Pub. Date: Feb. 2, 2006

(54) Modularized circuit component

(75) Inventors: Paul Wickett, Northville, MI (US); John Casari, Manchester, MI (US)

Correspondence Address: MICHAEL BEST & FRIEDRICH LLP, 100 EAST WISCONSIN AVENUE, MILWAUKEE, WI, 53202, US

(73) Assignee: Robert Bosch GmbH, Stuttgart, DE (US)

(21) Appl. No.: 10/910,179

(22) Filed: Aug. 2, 2004

(51) Int. Cl. H05K 7/02; H05K 7/06

(52) U.S. Cl. 361/807; 361/809; 361/810

(57) ABSTRACT

A modularized circuit component. The modularized circuit component includes a device having an identifying feature, an electrical terminal, and at least one of a mechanical plug and a mechanical receptacle. The modularized circuit component further includes a support block having an identifying feature that is substantially the same as the identifying feature of the device, at least one of a mechanical plug and a mechanical receptacle to interface with the at least one of a mechanical plug and a mechanical receptacle of the device, and an electrical terminal configured to interface with a circuit board. The identifying feature of the device and of the support block may comprise a texture, a color, a shape, or the like. In some embodiments, the device included in the modularized circuit component is a circuit protection device such as a fuse or a relay.

### FIELD OF INTEREST

Embodiments of the invention generally relate to packaging circuit components in modules. More specifically, embodiments of the invention relate to packaging circuit protection devices into modules to ease installation and replacement

### BACKGROUND OF THE INVENTION

Electrical components or systems are often coupled with circuit protection devices such as fuses and relays in order to protect the wiring of the electrical components. The circuit protection devices regulate and limit the amount of current provided to the wiring of the electrical components either by breaking a connection, detouring, buffering, or consuming the excess power. Objects utilizing a large amount of electrical components, for example, vehicles often also utilize a large amount of circuit protection devices to protect the large and often complex electrical system. Integrating the circuit protection devices into the electrical system is often a daunting task. Each circuit protection device requires specific placement and wiring. Placing a circuit protection device in the wrong location or placing the wrong type of circuit protection device in a location can damage a number of electrical components or even the entire electrical system.

Circuit boards containing one or more electrical components may be precisely configured in an arrangement that provides the necessary connections, power, and grounding for both the electrical components and corresponding circuit protection devices. If the arrangement of the electrical components changes, however, the circuit board configuration may need to be redesigned. Replacing the circuit protection devices may also require the resoldering of connections and can disrupt a number of components also contained on the circuit board.

### SUMMARY OF THE INVENTION

In one embodiment, the invention provides a modularized circuit component. The modularized circuit component includes a device having an identifying feature, an electrical terminal, and at least one of a mechanical plug and a mechanical receptacle. The modularized circuit component further includes a support block having an identifying feature that is substantially the same as the identifying feature of the device, at least one of a mechanical plug and a mechanical receptacle to interface with the at least one of a mechanical plug and a mechanical receptacle of the device, and an electrical terminal configured to interface with a circuit board. The identifying feature of the device and of the support block may comprise a texture, a color, a shape, or the like. In some embodiments, the device included in the modularized circuit component is a circuit protection device such as a fuse or a relay.

In another embodiment, the invention provides a circuit module that includes a circuit board; a plurality of devices, each device having an identifying feature, an electrical terminal, and a mechanical plug; a plurality of support blocks, each support block having an identifying feature, a mechanical receptacle to receive at least one plug of at least one device, and an electrical terminal configured to interface with the circuit board, where each electrical terminal of each support block is substantially identical to one another, and where at least some of the identifying features of the plurality of support blocks are substantially the same as at least some of the identifying features of at least some of the plurality of devices. The identifying features of the plurality of devices and of the plurality of support blocks may comprise a texture, a color, a shape, or the like. In some embodiments, the plurality of devices consists of circuit protection devices such as fuses or relays.

In another embodiment, the invention provides a method of assembling a circuit module. The method includes providing a circuit board; providing a plurality of devices, each device having an identifying feature, an electrical terminal, and a mechanical interface; providing a plurality of support blocks, each support block having an identifying feature, a mechanical interface to interact with at least one plug of at least one mechanical interface of at least one of the plurality of devices, and an electrical terminal configured to interface with the circuit board, where each electrical terminal of each support block is substantially identical to one another, and where at least some of the identifying features of the plurality of support blocks are substantially the same as at least some of the identifying features of at least some of the plurality of devices; associating each of the plurality of devices with a support block; and associating each of the support blocks with the circuit board.

In yet another embodiment, the invention provides a system for controlling electrical connections. The system includes a circuit board; and a circuit protection module having an identifying feature and configured to interface with the circuit board and to interface with a circuit protection device having an identifying feature, where the identifying feature of the circuit protection device is the same as the identifying feature of the circuit protection module. The identifying feature of the circuit protection device and of the circuit protection module may comprise a texture, a color, a shape, or the like. In some embodiments, the circuit protection module further includes one or more terminals configured to interface with the circuit board through a pin and paste connection and may also include a mechanical key also configured to interface with the circuit board.

In another embodiment, the invention provides a junction box module. The junction box module includes a circuit protection module having a support block with one or more terminals and a housing with an identifying feature and containing a circuit protection device having an identifying feature, where the identifying feature of the circuit protection device is the same as the identifying feature of the housing; and a circuit board configured to interface with the one or more terminals of the support block. The circuit board included in the junction box module may be configured to provide power to the circuit protection module. The circuit protection device may also be configured to be removable from the circuit protection component.

In yet another embodiment of the invention, a method of assembling a circuit protection module is provided. The method includes means for attaching a circuit protection device having an identifying feature to a support block having an identifying feature and one or more terminals where the identifying feature of the support block is the same as the identifying feature of the circuit protection device; and means for attaching the one or more terminals of the support block to a circuit board. In some embodiments, the circuit protection device further includes a mechanical interface.

Additional objects and aspects of embodiments of the invention are illustrated in the drawings and provided in the subsequent description.

### BRIEF DESCRIPTION OF THE DRAWINGS

In the drawings:

FIG. 1 is a front perspective view of an exemplary circuit protection device.

FIG. 2 is a bottom perspective view of the circuit protection device of FIG. 1.

FIG. 3 is an exploded view of an exemplary circuit protection module containing the circuit protection device of FIG. 1.

FIG. 4 is a front perspective view of an exemplary circuit protection module containing the circuit protection device of FIG. 1.

FIG. 5 is bottom perspective view of the circuit protection module of FIG. 2.

FIG. 6 is a side perspective view of an exemplary housing including a mechanical receptacle.

FIG. 7 is a front perspective view of another exemplary circuit protection module.

FIG. 8 is a bottom perspective view of the circuit protection module of FIG. 4.

FIG. 9 is a top perspective view of a circuit board containing a number of circuit protection modules.

### DETAILED DESCRIPTION

Before embodiments of the invention are explained in detail, it is to be understood that the invention is not limited in its application to the details of the examples set forth in the following description or illustrated in the drawings. The invention is capable of other embodiments and of being practiced or carried out in a variety of applications and in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. The terms “mounted,” “connected,” and “coupled” are used broadly and encompass both direct and indirect mounting, connecting, and coupling. Further, “connected” and “coupled” are not restricted to physical or mechanical connections or couplings.

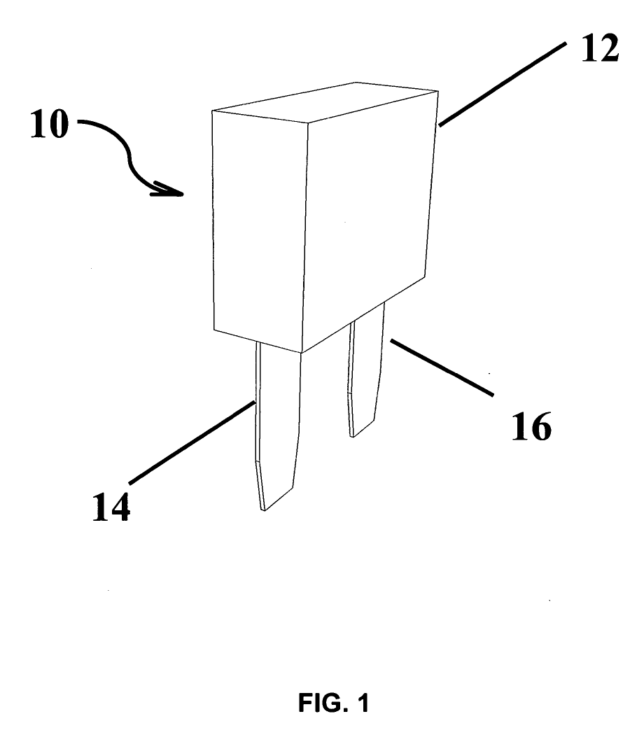

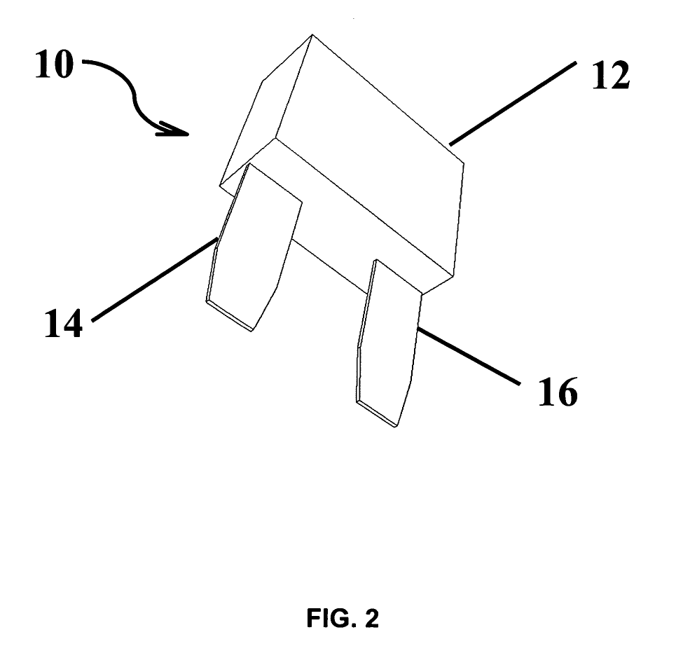

FIGS. 1 and 2 are perspective views of an exemplary circuit protection device 10. In some embodiments, the circuit protection device 10 may be a fuse, relay, circuit breaker, or the like. The circuit protection device 10 may include a housing 12 that encloses the internal circuitry of the circuit protection device 10. The internal circuitry of the circuit protection device 10 may include a conductor (not shown). The conductor may be a filament or piece of metal that has a lower melting point than the wire the circuit protection device is protecting. The material, size, position, or the like, of the conductor may be configured or calibrated so that when a limiting current is reached, enough heat is generated to melt the conductor and consequently break the circuit so that the excessive current does not reach the wiring of an electrical component such as a cooling fan, an anti-lock brake pump, a engine control unit, a car radio, or the like.

The housing 12 may have an identifying feature that allows different types of circuit protection devices to be identified. For example, the housing 12 of fuses of with certain amperage may be a particular color. The housing 12 may incorporate a texture, a size, a shape, a symbol, or any combination thereof, that identifies a type of circuit protection device 10. The identifying feature may provide a quick reference for determining the type of circuit protection device included in an electrical system and may also provide an easy replacement safeguard to ensure the correct circuit protection device is inserted in the correct location. For example, red fuses should be replaced with red fuses. The housing 12 of the circuit protection device may also shield the conductor or similar circuitry from dust, debris, or physical forces that may cause the circuitry to break or malfunction.

The circuit protection device 10 may also include one or more electrical terminals. The circuit protection device illustrated in FIGS. 1 and 2 has two terminals 14 and 16, although any number of terminals is possible. The terminals 14 and 16 may be configured to interface with a circuit board. The terminals 14 and 16 are connectable to the internal circuitry of the circuit protection device 10 and provide an input and output for current to pass through the internal circuitry. The current is received by one terminal, processed and regulated by the circuitry contained within the circuit protection device 10, and may be output by a second terminal.

In some embodiments, the terminals 14 and 16 are configured to perform as mechanical keys or plugs. Mechanical keys restrict the connection of components that are not configured to be connected. For example, a fuse of a given amperage may be required at a specific receptacle of the circuit board. Placing a fuse with any other amperage may result in possible damage to an electrical component. The receptacle of the circuit board may be configured to accept only mechanical keys of a physical terminal configuration that corresponds to the required circuit protection device. The terminals of different types of circuit protection devices, such as fuses with different amperages, may have unique configurations that limit the placement of the circuit protection device 10. The terminals 14 and 16 of different types of circuit protection devices may be constructed of various materials, may be positioned in various alignments, and may include additional ribs, notches, or other physical alterations in order to distinguish one type of circuit protection device 10 from another. Alternatively, the circuit protection device 10 may include a separate mechanical key or physical appendage or rib (not shown) that does not operate as a terminal but limits the connectability of the circuit protection device. The shape or configuration of the circuit protection device 10 itself may also act as a mechanical key. Only receptacles with mechanical receptacles configured to accept the physical configuration of the mechanical key or plug may be able to connect to the circuit protection device 10.

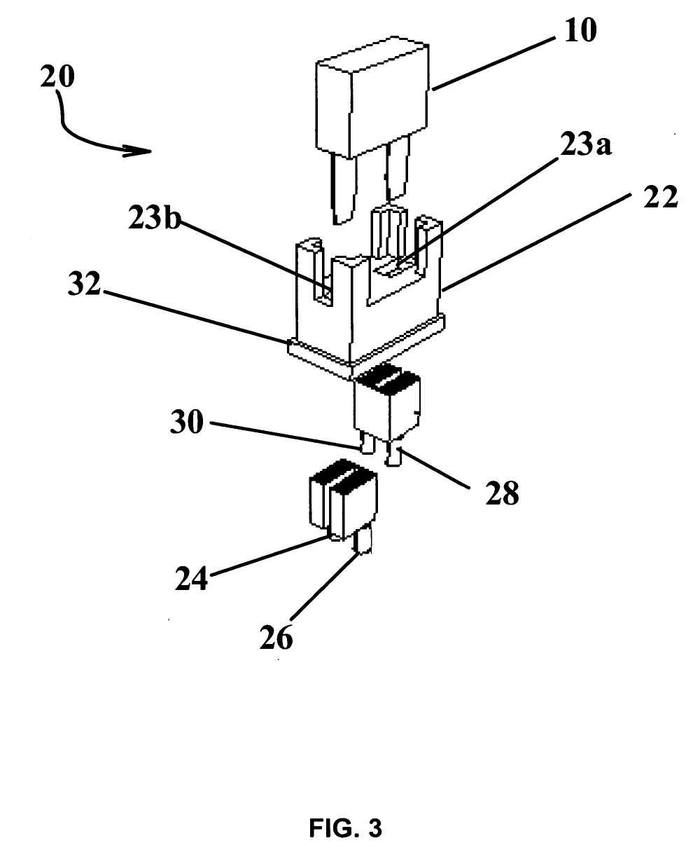

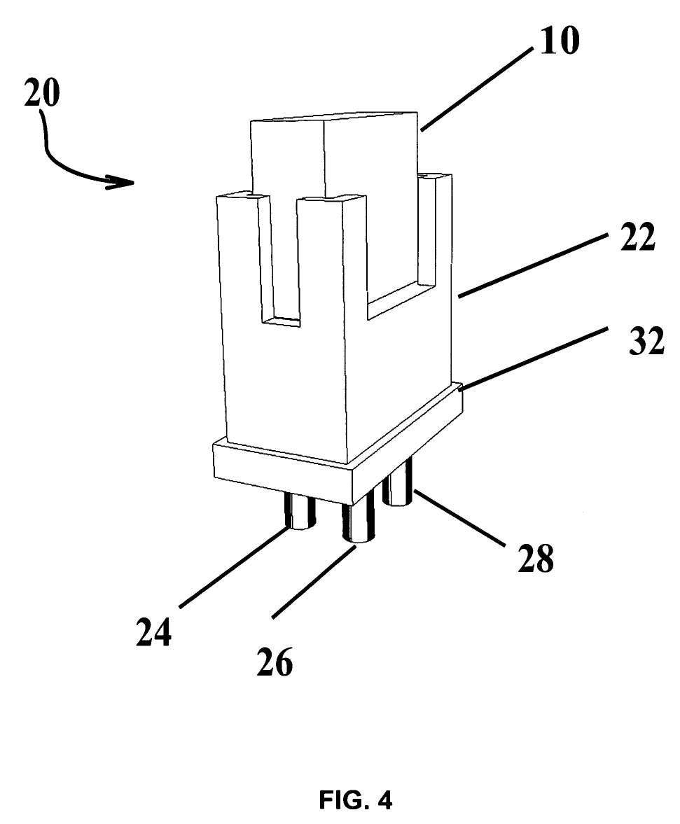

In some embodiments, the circuit protection device 10 is contained within a circuit protection module or modularized circuit component 20, as illustrated in FIGS. 3 and 4. Besides the circuit protection device 10, the circuit protection module 20 may also include a housing 22. The housing 22 may provide a receptacle for the circuit protection device 10. In the circuit protection module 20 illustrated in FIG. 4, the housing 22 provides a 4-walled receptacle. As seen in the exploded view of FIG. 3, the housing 22 may provide one or more terminal receptacles 23a and 23b for the terminals 14 and 16 of the circuit protection device 10. The terminal receptacles may be provided at the opposite end of the housing 22 from the open end where the circuit protection device 10 can be inserted and may provide a snap fit for the circuit protection device 10. The housing 22 provides support to the circuit protection device 10 while leaving the top of the circuit protection device 10 exposed for removal and replacement purposes. In some embodiments, the circuit protection module 20 is provided without the circuit protection device 10. Assembling the circuit protection module 20 may include inserting a circuit protection device 10 into the circuit protection module 20 through the open end of the housing 22.

Similar to the housing 12 of the circuit protection device 10, the housing 22 of the circuit protection module 20 may have identifying features. As previously described, the housing 22 may have a texture, shape, size, symbol, or any combination thereof. In some embodiments, the identifying feature of the housing 22 of the circuit protection module 20 may match the identifying feature of the circuit protection device 10 contained in the circuit protection module 20. Matching identifying features may include, but are not limited to, identical or corresponding colors, shapes, textures, or symbols. By matching the identifying features, even when the circuit protection device 10 is removed from the circuit protection module 20, an individual can determine what type of circuit protection device 10 to insert into the module 20.

The housing 22 may further provide support and shielding from dust, debris, and physical movement. In some embodiments, the housing 22 is a plastic module. The housing 22 may also be configured (with cooling fins and other known features (not shown)) to act as a heat sink and dissipate heat created by the circuit protection device 10.

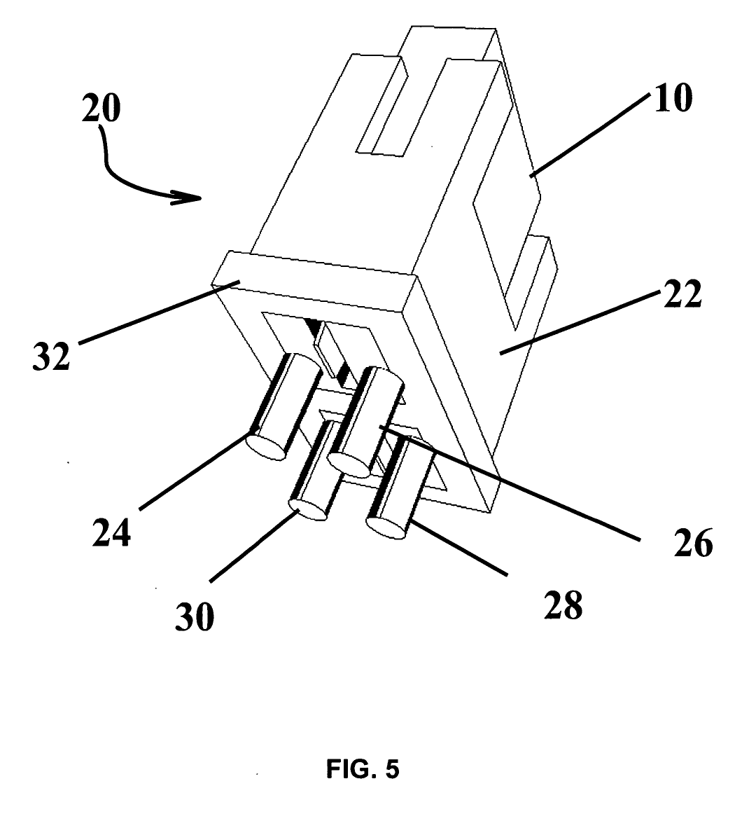

The circuit protection module 20 may also contain one or more terminals 24, 26, 28, and 30. The circuit protection module 20 illustrated in FIGS. 3-5 contains four terminals 24, 26, 28, and 30, although more or less terminal may be used. The circuit protection module 20, illustrated in an exploded view in FIG. 3, shows terminal blocks that each contain two terminals. The terminals may be separate components within the circuit protection module 20 or may be supplied as a block or group of terminals. The terminals 24, 26, 28, and 30 of the circuit protection module may be configured to interface with a circuit board. The terminals 24, 26, 28, and 30 may be configured to interface with specifically designated receptacles of a circuit board or may be configured to interface with standard receptacles. By designing the terminals 24, 26, 28, and 30 to interface with standard receptacles of a circuit board, the circuit protection device 20 can be moved as needed. The ability to move the circuit protection module 20 reduces the complexity of designing a circuit board configuration and limits the modifications required when the design is changed.

The terminals 24, 26, 28, and 30 may be configured to attach to a circuit board. The terminals 24, 26, 28, and 30 may be wave soldered to a circuit board by threading or inserting the terminals into, and possibly through, the circuit board. The terminals 24, 26, 28, and 30 may also be surface mounted on a circuit board using gull wings that melt when heated. The melted gull wings solder the terminals 24, 26, 28, and 30 to the circuit board. Alternatively, the terminals may be attached to a circuit board through a pin and paste method. The pin and paste method involves inserting terminals into the circuit board where the length of the terminal legs is about the same length as the thickness or depth of the receptacles of the circuit board. The top of the circuit board may contain solder that when heated flows into the receptacles of the circuit board and around the inserted terminals. Upon surrounding the inserted terminals, the solder forms a connection between the inserted terminals and the receptacles of the circuit board. The terminals may also be selective-soldered, hand-soldered, laser-welded, glued, press-fit or the like to the circuit board or other substrate material configured to define an electrical circuit.

The housing 22 with the attached terminals 24, 26, 28 and 30 may rest on a support block 32. The support block 32 provides a foundation for the circuit protection module 20. The support block 32 may rest on top of a circuit board or other interface connectable to the module 20. As described for the housing 22, the support block 32 may also contain an identifying feature such as a color, size, shape, texture, symbol, or combination thereof. Similar to the housing 22, the identifying feature of the support block 32 may match the identifying feature of the housing 22 and/or the circuit protection device 10. The support block 32 may also be configured (with cooling fins and other known features) to act as a heat sink for the circuit protection device 10. In some embodiments, the housing 22 is made from a metallic material and the support block 32 may be configured to electrically isolate the housing 22 from the circuit board and terminals 24, 26, 28, and 30. The support block 32 may also be configured to absorb or insulate any heat generated by the circuit protection device 10. The support block 32 may also protect other components also connected to the circuit board from experiencing interference from heat or energy generated by the circuit protection device 10.

In some embodiments, the support block 32 and housing 22 may be incorporated into one part. The support block 32 may be also be configured to provide terminal receptacles for the circuit protection device 10 as previously described for the housing 22.

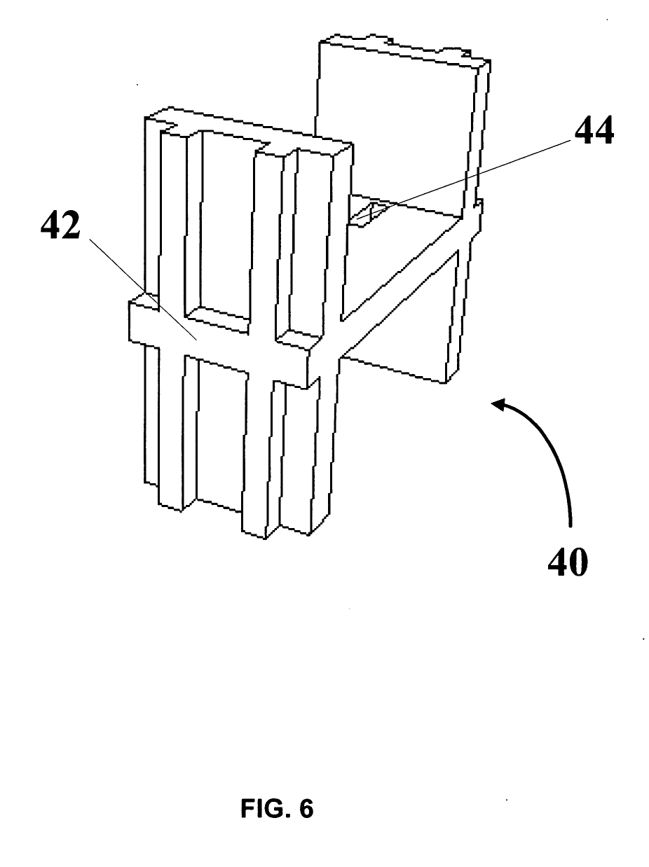

FIG. 6 illustrates an exemplary housing 40 containing a mechanical receptacle 42 that may replace the housing 22 of the circuit protection device 20 illustrated in FIGS. 3-5. As previously described, the circuit protection device 10 may include a mechanical key that limits the type of receptacle or component that the protection device 10 can be inserted in. The ridges on the outside of the housing 40, which create the mechanical receptacle 42, may be configured to allow only “matching” circuit protection devices 10 to be inserted into the housing 22. “Matching” circuit protection devices 10 may be devices 10 whose mechanical keys physically fit within the mechanical receptacle(s) 42 of the housing 40. The housing 40 illustrated in FIG. 6 may be constructed so that the key or physical shape of the circuit protection device 10 fits into the mechanical shape of the ridges. By interfacing the mechanical key of the circuit protection device to the mechanical receptacle 42 of the housing 40, the terminal(s) of the inserted circuit protection device can connect with terminal receptacle(s) 44 of the housing 40. Only terminals of circuit protection devices whose mechanical keys physically match or fit the mechanical receptacle of the housing 40 are able to interface with the terminal receptacle(s) 44 of the housing 40. The mechanical receptacle 42 provides a safeguard for ensuring that a correct circuit protection device is inserted into a circuit protection module. In contrast to the configuration just described, in some embodiments, the circuit protection device 10 has a mechanical receptacle and the housing 22 or 40 or circuit protection module 20 has a corresponding mechanical key.

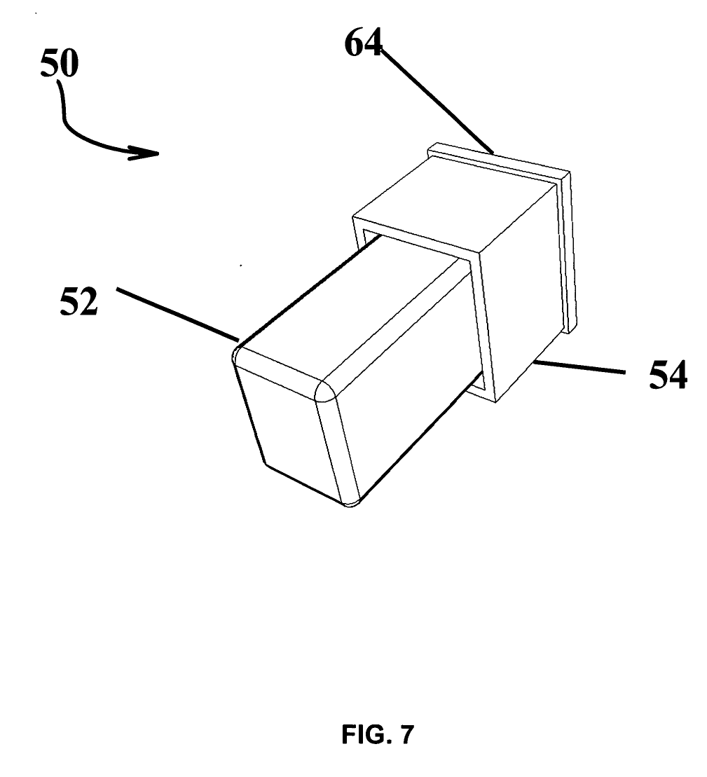

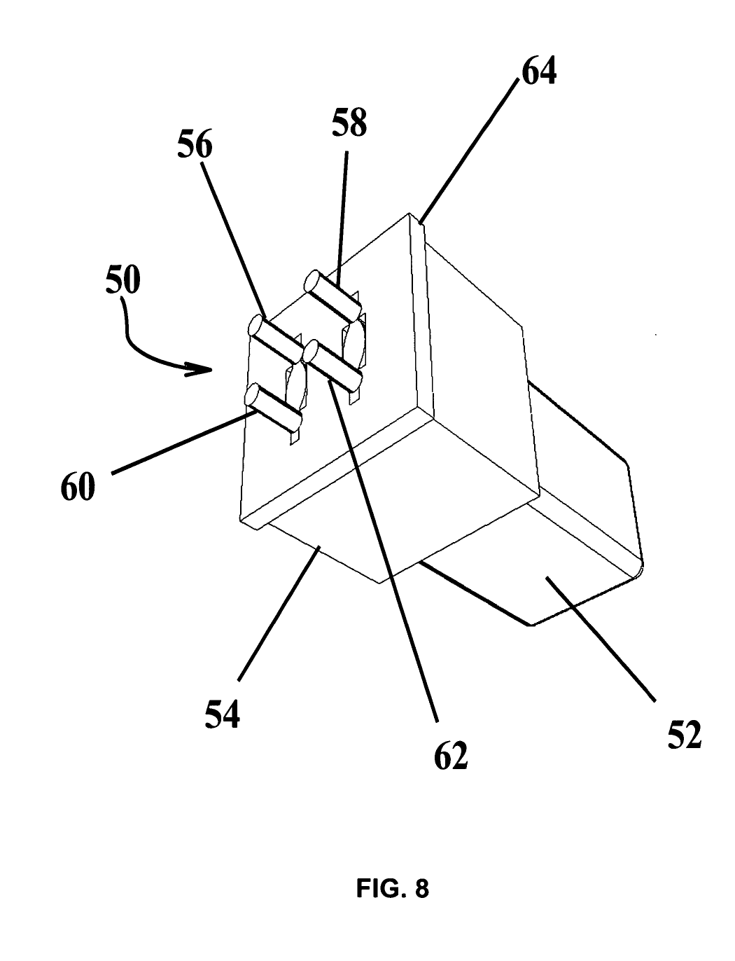

FIGS. 7 and 8 illustrate another exemplary circuit protection module 50. The circuit protection module 50 contains a circuit protection device 52, a housing 54, four terminals 56, 58, 60, and 62, and a support block 64. The circuit protection device 52 may be a different type of circuit protection device than the circuit protection device 10. For example, the circuit protection device 52 and circuit protection device 10 may both be fuses but may have different amperage ratings. The circuit protection device 52 may also be a fuse and the circuit protection device 10 may be a relay. The circuit protection module 50 may be specifically configured to house and connect to a particular type of circuit protection device or may be configured to connect to a number of different types of circuit protection devices.

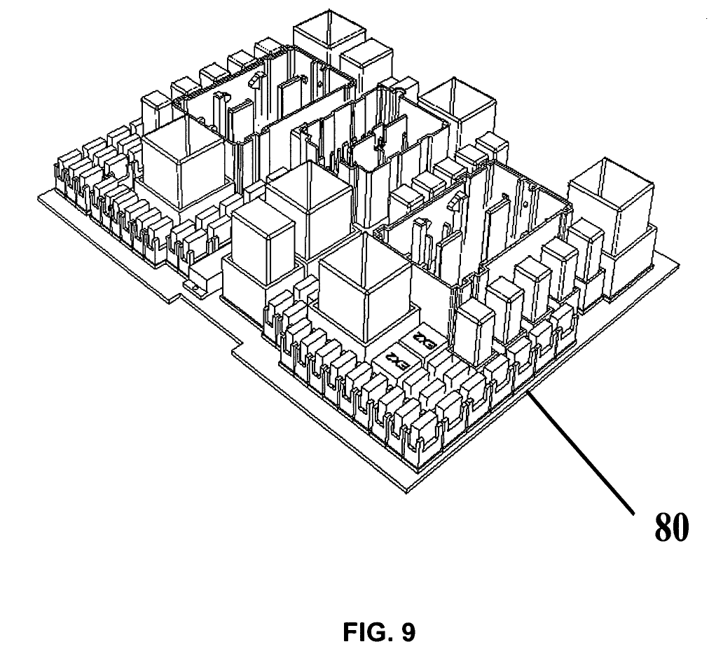

In some embodiments, the terminals 56, 58, 60, and 62 of the circuit protection module 50 are identical to the terminals 24, 26, 28, and 30 of the circuit protection module 20. The terminals may be identical to allow the circuit protection modules 20 and 50 to be moved and positioned in various locations on a circuit board. FIG. 9 illustrates a circuit board 80 containing a number of circuit protection modules. The circuit board 80 may be part of a junction box or similar system for controlling electrical connections or may be part of a circuit module such as a fuse panel. By packaging each circuit protection device individually in a circuit protection module, discrete circuit protection devices can be repositioned, removed, added, or the like, without disturbing the overall configuration of the circuit board 80. As previously described, the matching or corresponding identifying features of the housings 22 and 54 of the circuit protection devices 10 and 52 may provide visual or tactical characteristics that guide the proper installation of the proper circuit protection devices. The mechanical key or plug properties of the circuit protection devices 10 and 52 and the associated mechanical receptacle properties of the circuit protection modules 20 and 50, or more particularly, the housings 22 and 54, also provide a fool-proof system of restricting improper installations and replacements.

The modular construction of the circuit protection modules 20 and 50 also allow circuit protection devices such as fuses and relays, which often require replacement, to be quickly and efficiently replaced without replacing the entire module. The reusability of the module and the safe-guards provided by the module help reduce costs and provide preventive measures for limiting time and cost spent repairing electric systems due to improper installation or replacement of circuit protection devices.

It should be understood that other packaged electrical devices may be used in place of circuit protection devices. The circuit protection device 10 and 52 may be replaced by other packaged electrical components such as gates, buffers, inverters, or the like that may need to be replaced, relocated, removed, or added to a circuit board.

It should also be understood that in some embodiments, the mechanical plug may be configured on the circuit protection module 20 rather than on the circuit protection device 10. The circuit protection device 10 may similarly include the mechanical receptacle rather than the circuit protection module 20.

Various features and aspects of the invention are set forth in the following claims.

1. A modularized circuit component comprising:
a device having an identifying feature, an electrical terminal, and at least one of a mechanical plug and a mechanical receptacle; and
a support block having an identifying feature that is substantially the same as the identifying feature of the device, at least one of a mechanical plug and a mechanical receptacle to interface with the at least one of a mechanical plug and a mechanical receptacle of the device, and an electrical terminal configured to interface with a circuit board.

2. A modularized circuit component as claimed in claim 1, wherein the identifying feature of the device includes a texture.

3. A modularized circuit component as claimed in claim 1, wherein the identifying feature of the device includes a color.

4. A modularized circuit component as claimed in claim 1, wherein the identifying feature of the device includes a shape.

5. A modularized circuit component as claimed in claim 1, wherein the identifying feature of the device includes a symbol.

6. A modularized circuit component as claimed in claim 1, wherein the device includes a fuse.

7. A modularized circuit component as claimed in claim 1, wherein the device includes a relay.

8. A modularized circuit component as claimed in claim 1, wherein the support block is configured to act as a heat sink.

9. A circuit module comprising:
a circuit board;
a plurality of devices, each device having an identifying feature, an electrical terminal, and a mechanical plug;
a plurality of support blocks, each support block having an identifying feature, a mechanical receptacle to receive at least one plug of at least one device, and an electrical terminal configured to interface with the circuit board, where each electrical terminal of each support block is substantially identical to one another, and where at least some of the identifying features of the plurality of support blocks are substantially the same as at least some of the identifying features of at least some of the plurality of devices.

10. A circuit module as claimed in claim 9, wherein the identifying feature of at least some of the plurality of devices includes a texture.

11. A circuit module as claimed in claim 9, wherein the identifying feature of at least some of the plurality of devices includes a color.

12. A circuit module as claimed in claim 9, wherein the identifying feature of at least some of the plurality of devices includes a shape.

13. A circuit module as claimed in claim 9, wherein the identifying feature of at least some of the plurality of devices includes a symbol.

14. A circuit module as claimed in claim 9, wherein at least some of the plurality of devices include a fuse.

15. A circuit module as claimed in claim 9, wherein at least some of the plurality of devices include a relay.

16. A circuit module as claimed in claim 9, wherein at least some of the plurality of support blocks are configured to act as a heat sink.

17. A method of assembling a circuit module, the method comprising:
providing a circuit board;
providing a plurality of devices, each device having an identifying feature, an electrical terminal, and a mechanical interface;
providing a plurality of support blocks, each support block having an identifying feature, a mechanical interface to interact with at least one plug of at least one mechanical interface of at least one of the plurality of devices, and an electrical terminal configured to interface with the circuit board, where each electrical terminal of each support block is substantially identical to one another, and where at least some of the identifying features of the plurality of support blocks are substantially the same as at least some of the identifying features of at least some of the plurality of devices;
associating each of the plurality of devices with a support block; and
associating each of the support blocks with the circuit board.

18. The method of assembling a circuit protection module as claimed in claim 17, further comprising shielding at least some of the plurality of devices with a housing.

19. A system for controlling electrical connections, the system comprising:
a circuit board; and
a circuit protection module having an identifying feature and configured to interface with the circuit board and to interface with a circuit protection device having an identifying feature, where the identifying feature of the circuit protection device is the same as the identifying feature of the circuit protection module.

20. A system as claimed in claim 19, wherein the identifying feature of the circuit protection module is a color.

21. A system as claimed in claim 19, wherein the identifying feature of the circuit protection modules is a texture.

22. A system as claimed in claim 19, wherein the identifying feature of the circuit is a shape.

23. A system as claimed in claim 19, wherein the identifying feature of the circuit is a symbol.

24. A system as claimed in claim 19, wherein the circuit protection module further includes one or more terminals configured to interface with the circuit board.

25. A system as claimed in claim 24, wherein the one or more terminals of the circuit protection module interface with the circuit board through a pin and paste connection.

26. A system as claimed in claim 19, wherein the circuit protection module further includes a housing.

27. A system as claimed in claim 26, wherein the housing is configured to act as a heat sink.

28. A system as claimed in claim 26, wherein the housing has an identifying feature that is the same as the identifying feature of the circuit protection module.

29. A system as claimed in claim 19, wherein the circuit protection device further includes a mechanical key.

30. A system as claimed in claim 29, wherein the circuit protection module is further configured to accept the mechanical key of the circuit protection device.

31. A junction box module, the module comprising:
a circuit protection module having a support block with one or more terminals and a housing with an identifying feature and containing a circuit protection device having an identifying feature, where the identifying feature of the circuit protection device is the same as the identifying feature of the housing; and a circuit board configured to interface with the one or more terminals of the support block.

32. A junction box module as claimed in claim 31, wherein the housing acts as a heat sink.

33. A junction box module as claimed in claim 31, wherein the circuit board is configured to provide current to the circuit protection module.

34. A junction box module as claimed in claim 31, wherein the circuit protection device is removable from the circuit protection module.

35. A junction box module as claimed in claim 31, wherein the one or more terminals of the support block interface with the circuit board with a pin and paste method.

36. A junction box module as claimed in claim 31, wherein the one or more terminals of the support block are configured to move relative to the housing.

37. A junction box module as claimed in claim 31, wherein the circuit protection device further contains a mechanical key.

38. A junction box module as claimed in claim 37, wherein the mechanical key permits the circuit protection device from being contained within a circuit protection module where the identifying feature of the housing is not the same as the identifying feature of the circuit protection device.

39. A junction box module as claimed in claim 31, wherein the identifying feature of the circuit protection device is a color.

40. A junction box module as claimed in claim 31, wherein the identifying feature of the circuit protection device is a texture.

41. A junction box module as claimed in claim 31, wherein the identifying feature of the circuit protection device is a shape.

42. A junction box module as claimed in claim 31, wherein the identifying feature of the circuit protection device is a symbol.

43. A junction box module as claimed in claim 31, wherein the support block has an identifying feature where the identifying feature of the support block is the same as the identifying feature of the circuit protection device.

44. A circuit protection module comprising:
means for attaching a circuit protection device having an identifying feature to a support block having an identifying feature and one or more terminals, where the identifying feature of the support block is the same as the identifying feature of the circuit protection device; and
means for attaching the one or more terminals of the support block to a circuit board.

45. A circuit protection module as claimed in claim 44, wherein the circuit protection device further includes a mechanical interface.

46. A circuit protection module as claimed in claim 45, wherein the means attaching the circuit protection device to the support block further includes means for accepting the mechanical interface of the circuit protection device by the support block.

47. A circuit protection module as claimed in claim 44, further comprising means for housing the circuit protection device.
